(19) United States
(12) Patent Application Publication
(10) Pub. No.: US 2025/0168548 A1
(43) Pub. Date: May 22, 2025

(54) DEVICE, SYSTEM AND METHOD FOR MICROPHONIC NOISE COMPENSATION

(71) Applicant: MOTOROLA SOLUTIONS, INC., Chicago, IL (US)

(72) Inventors: Jeet K. PAWANI, Sunrise, FL (US); Daniel PLAZAS, Pembroke Pines, FL (US); Rajesh Baliram SINGH, Davie, FL (US)

(21) Appl. No.: 18/513,847

(22) Filed: Nov. 20, 2023

(51) Int. Cl. H04R 1/08

(52) U.S. Cl. CPC H04R 1/08; H04R 2201/029; H04R 2410/03; H04R 2430/01; H04R 2499/10

(57) ABSTRACT

A device, system, and method for microphonic noise compensation is provided. The device comprises: a speaker; a receiver; an audio processor configured to: process audio received via the receiver; and output processed audio to the speaker; a microphonic detection engine; and a microphonic compensation engine. The microphonic detection engine configured to: search for microphonic noise in the processed audio according to one or more predetermined microphonic parameters; and when the microphonic noise is detected: output a microphonic indicator to the microphonic compensation engine to cause the microphonic compensation engine to compensate for the microphonic noise in the audio. The microphonic compensation engine configured to: receive the microphonic indicator; and responsively compensate for the microphonic noise in the audio received via the receiver, prior to processing of the audio by the audio processor.

### BACKGROUND OF THE INVENTION

Communication devices for first responders, such as land-mobile radios (LMRs), may emit audio via a speaker. Such communication devices generally include a radio-frequency (RF) mixer and a voltage-controlled oscillator (VCO) which convert audio signals received, via a receiver, into audio of a format suitable for processing by an audio processor, such as a digital signal processor (DSP). However, first responders may operate the communication devices at volumes such that processed audio output by a speaker causes vibrations at the VCO, which may translate into noise introduced into the audio output from the RF mixer. Such noise is referred to as microphonic noise and generally manifests as a howling sound output by the speaker, which may, in turn, cause more vibrations at the VCO, increasing the microphonic noise in a feedback loop. Such microphonic noise may obscure audio output by the speaker, such that a first responder operating the communication device may not hear mission critical information.

### BRIEF DESCRIPTION OF THE SEVERAL VIEWS OF THE DRAWINGS

In the accompanying figures similar or the same reference numerals may be repeated to indicate corresponding or analogous elements. These figures, together with the detailed description, below are incorporated in and form part of the specification and serve to further illustrate various embodiments of concepts that include the claimed invention, and to explain various principles and advantages of those embodiments.

FIG. 1 is a device for microphonic noise compensation, in accordance with some examples.

FIG. 2 is a device diagram showing a device structure of the device for microphonic noise compensation, in accordance with some examples.

FIG. 3 is a flowchart of a method for microphonic noise compensation, in accordance with some examples.

FIG. 4 depicts the device structure of FIG. 1 implementing a method for microphonic noise compensation, in accordance with some examples.

FIG. 5 depicts the device structure of FIG. 1 continuing to implement a method for microphonic noise compensation, in accordance with some examples.

FIG. 6 depicts the device structure of FIG. 1 implementing a method for microphonic noise compensation, in accordance with some examples.

FIG. 7 depicts the device structure of FIG. 1 continuing to implement a method for microphonic noise compensation, in accordance with some examples.

Skilled artisans will appreciate that elements in the figures are illustrated for simplicity and clarity and have not necessarily been drawn to scale. For example, the dimensions of some of the elements in the figures may be exaggerated relative to other elements to help improve understanding of embodiments of the present disclosure.

The system, apparatus, and method components have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

### DETAILED DESCRIPTION OF THE INVENTION

Microphonic noise at a communication device may obscure audio output by a speaker such that a first responder operating the communication device may not hear mission critical information. While such microphonic noise may be at least partially mitigated using physical sound baffling and/or shields between the speaker and a voltage-controlled oscillator (VCO), such sound baffling and/or shields adds to the weight and cost of the communication device. Furthermore, such an approach may require that, prior to shipping, the communication device be connected to an external analyzer used to measure microphonic feedback, to determine the nature of the baffling and the shields. Alternatively, or in addition, while permanent software and/or hardware filtering may be added to the communication device, such software and/or hardware filtering may degrade the quality of the audio at the communication device. Thus, there exists a need for an improved technical method, device, and system for microphonic noise compensation.

Hence, provided herein is a device, system, and method for microphonic noise compensation. In particular a communication device is provided with a microphonic detection engine, and a microphonic compensation engine, for example on an audio path between a radio-frequency (RF) mixer and a speaker of the communication device, that includes an audio processor between the microphonic detection engine the microphonic compensation engine. In particular, on the audio path, the communication device may comprise (e.g. in order), an RF mixer coupled to a VCO (which may be components of the receiver and/or a radio frequency integrated circuit (RFIC)), an analog-to-digital converter (ADC) (e.g. which digitized analog output from the RF mixer), the microphonic compensation engine, the audio processor, the microphonic detection engine, and the speaker, though any suitable components may be on the audio path. The RF mixer outputs audio received via an antenna and the receiver, and the like, to the audio processor, and the audio processor processes the audio into processed audio, suitable for output by the speaker. A digital-to-analog converter (DAC) may convert the processed audio from a digital format to an analog format, and an audio power amplifier may amplify the analog processed audio to voltages suitable for driving the speaker. However, the speaker outputting the amplified analog processed audio as sound may cause the VCO to vibrate, causing the microphonic noise.

The microphonic detection engine searches for microphonic noise in processed audio output by the audio processor, for example according to one or more predetermined microphonic parameters, that may define levels and/or ranges of microphonic noise in processed audio. When microphonic noise is detected, the microphonic detection engine outputs a microphonic indicator to the microphonic compensation engine to cause the microphonic compensation engine to compensate for the microphonic noise in the audio (e.g. prior to processing by the audio processor).

The microphonic compensation engine receives the microphonic indicator, and responsively compensates for the microphonic noise in the audio received via the receiver, prior to processing of the audio by the audio processor. For example, as a frequency, and the like, of microphonic noise may be predictable and/or may have been heuristically determined, the indicator may indicate a level and/or range of the detected microphonic noise, and the microphonic compensation engine may compensate for the microphonic noise according to such a level and/or range. Put another way, the microphonic compensation engine may subtract a signal from the audio corresponding to the microphonic noise, such that the microphonic noise is removed and/or reduced at the audio processed by the audio processor.

When the microphonic detection engine continues to detect microphonic noise, after the microphonic compensation engine compensates for microphonic noise, the microphonic compensation engine may again attempt to reduce the microphonic noise and/or the microphonic compensation engine may reduce the volume sound emitted by the speaker, to attempt to reduce microphonic noise via such volume reduction. Such a reduction in the sound emitted by the speaker may occur at the microphonic compensation engine, for example to reduce volume of audio output by the microphonic compensation engine. However, such a reduction in the sound emitted by the speaker may occur via other suitable component of the communication device. For example, the microphonic compensation engine may control any other suitable component of the communication device, such as the audio power amplifier, to reduce the processed audio. Regardless, the sound output by the speaker is reduced, which may reduce the microphonic noise due to a reduction of vibrations at the VCO.

In particular, the microphonic detection engine and the microphonic compensation engine may continue to respectively detect and compensate for the microphonic noise in a feedback loop, and, with each instance of the feedback loop, where the microphonic noise continues to be detected, the microphonic compensation engine reduces volume of sound output by the speaker, for example until a predetermined minimum volume is reached (e.g. of the audio and/or the processed audio).

An aspect of the present specification provides a device comprising: a speaker; a receiver; an audio processor configured to: process audio received via the receiver; and output processed audio to the speaker; a microphonic detection engine; and a microphonic compensation engine, the microphonic detection engine configured to: search for microphonic noise in the processed audio according to one or more predetermined microphonic parameters; when the microphonic noise is detected: output a microphonic indicator to the microphonic compensation engine to cause the microphonic compensation engine to compensate for the microphonic noise in the audio; the microphonic compensation engine configured to: receive the microphonic indicator; and responsively compensate for the microphonic noise in the audio received via the receiver, prior to processing of the audio by the audio processor.

Another aspect of the present specification provides a method comprising: processing, at an audio processor, audio received via a receiver to generate processed audio; searching, via a microphonic detection engine, for microphonic noise in the processed audio according to one or more predetermined microphonic parameters; when the microphonic noise is detected: outputting, via the microphonic detection engine, a microphonic indicator to a microphonic compensation engine; receiving, at the microphonic compensation engine, the microphonic indicator; responsively compensating, via the microphonic compensation engine, for the microphonic noise in the audio received via the receiver, prior to processing of the audio by the audio processor; and outputting, via the microphonic detection engine, the processed audio to a speaker.

A further aspect of the present specification provides a device comprising: a speaker; a receiver; an audio processor configured to: process audio received via the receiver; and output processed audio to the speaker; a microphonic detection engine; a microphonic compensation engine; and a computer-readable storage medium having stored thereon program instructions that, when executed by the microphonic detection engine and the microphonic compensation engine, cause the microphonic detection engine and the microphonic compensation engine to perform respective sets of operations comprising: searching, via the microphonic detection engine, for microphonic noise in the processed audio according to one or more predetermined microphonic parameters; and when the microphonic noise is detected: outputting, via the microphonic detection engine, a microphonic indicator to the microphonic compensation engine to cause the microphonic compensation engine to compensate for the microphonic noise in the audio; receiving, via the microphonic compensation engine, the microphonic indicator; and responsively compensating, via the microphonic compensation engine, for the microphonic noise in the audio received via the receiver, prior to processing of the audio by the audio processor.

Each of the above-mentioned embodiments will be discussed in more detail below, starting with example system and device architectures of the system in which the embodiments may be practiced, followed by an illustration of processing blocks for achieving an improved technical method, device, and system for microphonic noise compensation.

Example embodiments are herein described with reference to flowchart illustrations and/or block diagrams of methods, apparatus (systems) and computer program products according to example embodiments. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a special purpose and unique machine, such that the instructions, which execute via the processor of the computer or other programmable data processing apparatus, create means for implementing the functions/acts specified in the flowchart and/or block diagram block or blocks. The methods and processes set forth herein need not, in some embodiments, be performed in the exact sequence as shown and likewise various blocks may be performed in parallel rather than in sequence. Accordingly, the elements of methods and processes are referred to herein as “blocks” rather than “steps.”

These computer program instructions may also be stored in a computer-readable memory that can direct a computer or other programmable data processing apparatus to function in a particular manner, such that the instructions stored in the computer-readable memory produce an article of manufacture including instructions which implement the function/act specified in the flowchart and/or block diagram block or blocks.

The computer program instructions may also be loaded onto a computer or other programmable data processing apparatus that may be on or off-premises, or may be accessed via the cloud in any of a software as a service (SaaS), platform as a service (PaaS), or infrastructure as a service (IaaS) architecture so as to cause a series of operational blocks to be performed on the computer or other programmable apparatus to produce a computer implemented process such that the instructions which execute on the computer or other programmable apparatus provide blocks for implementing the functions/acts specified in the flowchart and/or block diagram block or blocks. It is contemplated that any part of any aspect or embodiment discussed in this specification can be implemented or combined with any part of any other aspect or embodiment discussed in this specification.

Herein, reference will be made to engines, which may be understood to refer to hardware, and/or a combination of hardware and software (e.g., a combination of hardware and software includes software hosted at hardware such that the software, when executed by the hardware, transforms the hardware into a special purpose hardware, such as a software module that is stored at a processor-readable memory implemented or interpreted by a processor), or hardware and software hosted at hardware and/or implemented as a system-on-chip architecture and the like.

Further advantages and features consistent with this disclosure will be set forth in the following detailed description, with reference to the drawings.

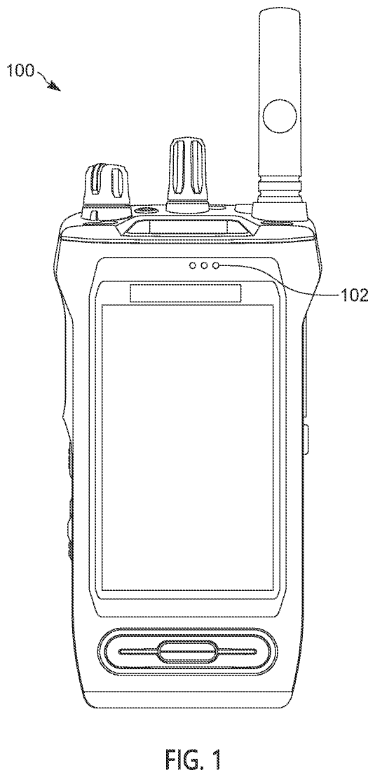

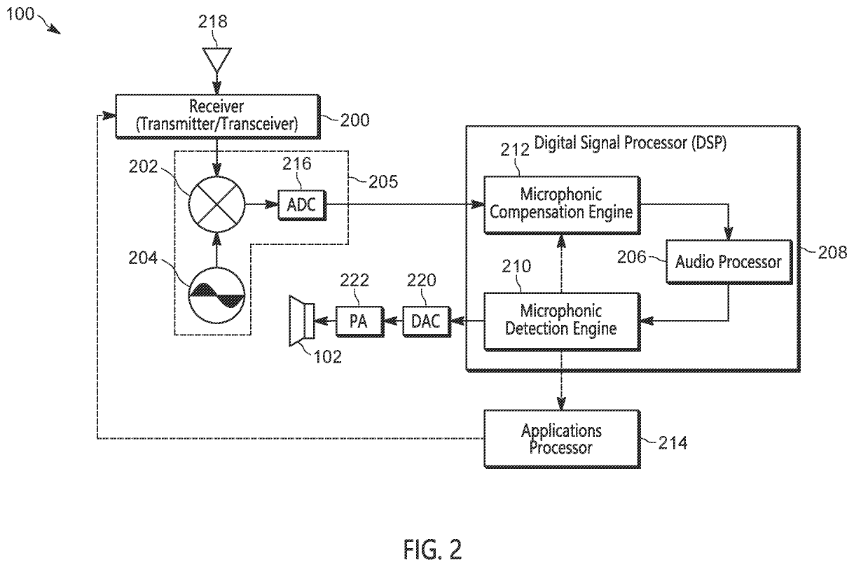

Attention is directed to FIG. 1 and FIG. 2 that respectively depict a perspective view, and a block diagram, of a communication device 100 comprising a speaker 102 and which performs microphonic noise compensation as described herein. The communication device 100 is interchangeably referred to hereafter as the device 100.

As depicted in FIG. 1, the device 100 comprises a mobile radio adapted for use by first responders, and the like, and may specifically a land mobile radio (LMR), a digital mobile radio (DMR), a two-way radio, a first responder radio, and the like, amongst other possibilities, and/or any other suitable communication device for assisting first responders in responding to incidents.

However, the device 100 may comprise any suitable portable device, partially portable device, and/or non-portable device that includes a receiver (e.g. and an RF mixer/VCO combination) and a speaker. In particular examples, the device 100 may comprise any suitable mobile communication device, any suitable portable device, cell phone, a radio, a body-worn camera (e.g., with audio functionality), a remote speaker microphone (RSM), a first responder device, a laptop computer, a headset, and the like, and/or any device that includes a microphone and provides audio data to an output device, as described herein.

With reference to FIG. 2, the device 100 comprises: the speaker 102; a receiver 200 (e.g., which, as depicted, may be provided with a transmitter and/or as a transceiver and hence may alternatively be referred to herein as a receiver/transceiver 200 and/or a receiver/transmitter 200), an RF mixer 202 and a VCO 204 (e.g., which, as depicted, may be components of an RFIC 205); an audio processor 206 (e.g. which may implemented at a digital signal processor (DSP) 208 and/or as a component of the DSP 208); a microphonic detection engine 210; a microphonic compensation engine 212; and an applications processor 214. While the microphonic detection engine 210 and the microphonic compensation engine 212 are depicted as components of the DSP 208, one or more of the microphonic detection engine 210 and the microphonic compensation engine 212 may be implemented separate from the DSP 208 and/or one or more of the microphonic detection engine 210 and the microphonic compensation engine 212 may be implemented by the applications processor 214.

The device 100 further comprises, as depicted, an analog-to-digital converter (ADC) 216, an antenna 218, a digital-to-analog converter (DAC) 220 and an audio power amplifier 222. The ADC 216 may, as depicted, be a component of the RFIC 205, and generally converts analog audio (e.g. audio received by the receiver 200), output by the RF mixer 202, to digital audio. The DAC 220 generally converts digital processed audio to analog audio for output by the speaker 102 as sound, and the audio power amplifier 222 amplifies the analog audio output by the DAC 220 to power levels suitable for driving the speaker 102.

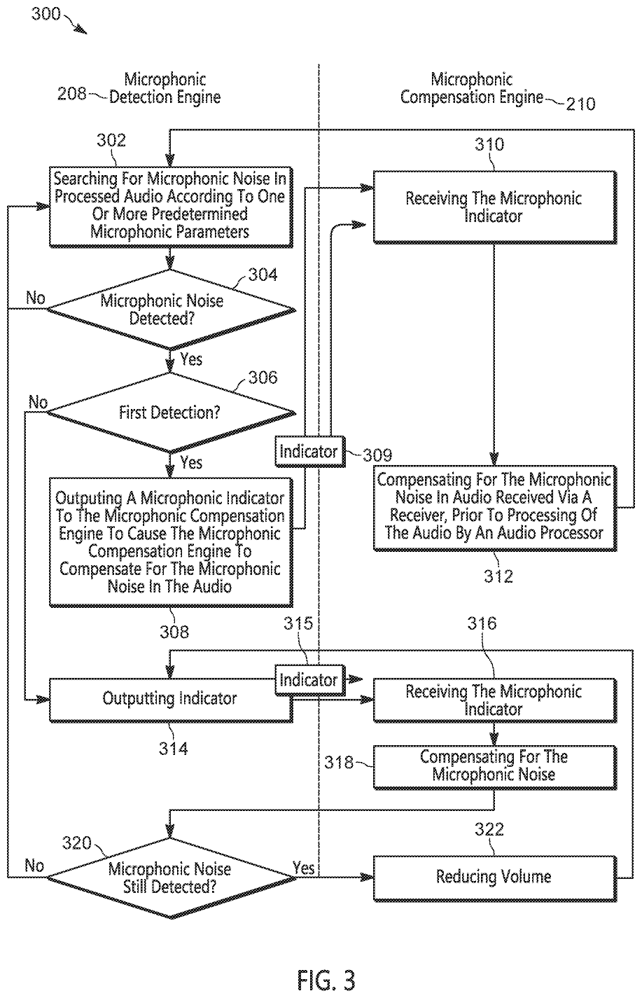

While not expressly depicted, the device 100 may further comprise any other suitable components including, but not limited to any suitable combination of read-only memory (ROM), random-access memory (RAM), modulators, demodulators, input/output interfaces, and the like. Such a memory may comprise a computer-readable storage medium having stored thereon program instructions that, when executed by the microphonic detection engine 210 and the microphonic compensation engine 212, cause the microphonic detection engine 210 and the microphonic compensation engine 212 to perform respective sets of operations comprising the blocks of the method of FIG. 3. Such a computer-readable storage medium and program instructions are understood to be represented in FIG. 1 as a component of one or more of the engines 210, 212, and the DSP 208, however such a computer-readable storage medium and program instructions may be separate from, but accessible to, the engines 210, 212, and the DSP 208.

The receiver 200, and/or a transceiver that combines the receiver 200 and a transmitter, may be adapted for communication with one or more of the Internet, a digital mobile radio (DMR) network, a Project 25 (P25) network, a terrestrial trunked radio (TETRA) network, a Bluetooth network, a Wi-Fi network, for example operating in accordance with an IEEE 802.11 standard (e.g., 802.11a, 802.11b, 802.11g), an LTE (Long-Term Evolution) network and/or other types of GSM (Global System for Mobile communications) and/or 3GPP (3^{rd} Generation Partnership Project) networks, a 5G network (e.g., a network architecture compliant with, for example, the 3GPP TS 23 specification series and/or a new radio (NR) air interface compliant with the 3GPP TS 38 specification series) standard), a Worldwide Interoperability for Microwave Access (WiMAX) network, for example operating in accordance with an IEEE 802.16 standard, and/or another similar type of wireless network.

Hence, a transceiver that combines the receiver 200 and a transmitter may include one or more transceivers that may include, but are not limited to, a cell phone transceiver, a DMR transceiver, P25 transceiver, a TETRA transceiver, a 3GPP transceiver, an LTE transceiver, a GSM transceiver, a 5G transceiver, a Bluetooth transceiver, a Wi-Fi transceiver, a WiMAX transceiver, and/or another similar type of wireless transceiver configurable to communicate via a wireless radio network.

The processors 206, 214 may include one or more logic circuits, one or more processors, one or more microprocessors, one or more GPUs (Graphics Processing Units), and/or the processors 206, 214 may include one or more ASIC (application-specific integrated circuits) and one or more FPGA (field-programmable gate arrays), and/or another electronic device.

The device 100 may further comprise any suitable combination of input devices and/or output devices, which may include, but is not limited to, buttons, a keyboard, a pointing device, a display screen, a touch screen, and the like.

Communication links between components of the device 100 are depicted in FIG. 2 as arrows, with directionality of audio and/or data flow indicated by directionality of the arrows. Furthermore, an audio path of the device 100 is indicated by solid arrows, data communication between the microphonic detection engine 210, the microphonic compensation engine 212 and the applications processor 214 is depicted with arrows having a shorter dash, and data communication between the applications processor 214, the receiver/transceiver 200 and the antenna 218 is depicted with arrows having a longer dash. Such distinctions are provided for clarity, to show types of data being processed at the device 100.

In general, the device 100 receives wireless audio signals, via the antenna 218 and the receiver 200, which are converted to audio of a format processable by the audio processor 206 at least via the VCO 204 providing a waveform to the RF mixer 202, and the pitch of the waveform is modulated via the RF mixer 202 based on the received wireless audio signal. In particular, the combination of the RF mixer 202 and the VCO 204 may convert audio signals from a MHz and/or GHz range to a kHz range, and the ADC 216 may convert the audio signals to digital audio.

Such audio (e.g. in a digital format, and downmixed to the kHz range) is provided to the audio processor 206, which processes the audio, and outputs processed audio, for conversion by the DAC 220 and the audio power amplifier 222 into a format suitable for playing by the speaker 102.

Generally, the audio processor 206 may be configured to: process audio received via the receiver 200; and output processed audio to the speaker 102 (e.g. via the DAC 220 and the audio power amplifier 222). For example the audio processor 206 may perform any suitable functionality on the audio, including, but not limited to, audio leveling, tier gaining, and the like. Audio leveling increases or reduces audio levels to predetermined levels commensurate with human hearing and/or levels that have been heuristically determined to be preferred by humans. Tier gaining may adjust overall volume of audio to a predetermined maximum volume level (e.g. but which may be adjusted as described herein).

As depicted, the speaker 102 may be positioned to output sound in a direction of the VCO 204, which may introduce microphonic noise into the audio output by the receiver 200. For example, due to the sound of the speaker 102, the VCO 204 outputs both a predetermined waveform the VCO 204 used by RF mixer 202, and noise due to vibration of the VCO 204 by the sound.

The microphonic detection engine 210 is configured to search for microphonic noise in the processed audio from the audio processor 206 according to one or more predetermined microphonic parameters. The one or more predetermined microphonic parameters may be heuristically determined at a factory, for example by measuring microphonic noise in an example device, similar to the device 100, to determine characteristics of such microphonic noise, such as a frequency and/or frequencies thereof, and levels and/or ranges thereof.

Alternatively, or in addition, the one or more predetermined microphonic parameters may be indicative of one or more predetermined microphonic audio data sets combined with one or more clean audio samples. For example, at the factory, microphonic noise may be measured and stored as one or more microphonic audio data sets, and the one or more microphonic audio data sets may be combined with clean audio samples representing audio output by audio processor 206 when no audio signal is being received at the receiver.

The microphonic detection engine 210 hence searches for such one or more predetermined microphonic parameters in the processed audio.

When the microphonic noise is detected, the microphonic detection engine 210 outputs a microphonic indicator to the microphonic compensation engine 212 to cause the microphonic compensation engine 212 to compensate for the microphonic noise in the audio received via the receiver 200. Output of the microphonic indicator to the microphonic compensation engine 212 may occur via the communication link indicated via the short dash arrow therebetween, depicted in FIG. 2.

The microphonic indicator may indicate a level of the microphonic noise and/or a range in which a level of the microphonic noise is located, for example in decibels. For example, when the microphonic noise is −5 dB, the microphonic indicator may indicate “−5 dB”, or the microphonic indicator may indicate that the microphonic noise is in a range of “−4 dB to −6 dB”, and the like, amongst other possibilities. The microphonic indicator may alternatively indicate a frequency and/or frequencies of the microphonic noise.

However, in some examples, the microphonic indicator may more simply comprise a flag and/or value, of a plurality of flags or values, that correspond to different ranges of microphonic noise. For example, a flag and/or value of “0” may indicate microphonic noise in a range of “greater than 0 dB”, a flag and/or value of “1” may indicate microphonic noise in a range of “0 dB to −2 dB”, a flag and/or value of “2” may indicate microphonic noise in a range of “−2 dB to −4 dB”, a flag and/or value of “3” may indicate microphonic noise in a range of “−4 dB to −6 dB”, and a flag and/or value of “4” may indicate microphonic noise in a range of “less than −6 dB”. As microphonic noise less than −6 dB may not be detectable and/or may not result in the aforementioned howling sound, a flag and/or value of “4” may indicate no microphonic noise and/or no microphonic noise detected.

The microphonic compensation engine 212 is configured to: receive the microphonic indicator; and responsively compensate for the microphonic noise in the audio received via the receiver 200, prior to processing of the audio by the audio processor 206.

For example, when the microphonic indicator specifically indicates a level (and/or frequency and/or frequencies of the microphonic noise), the microphonic compensation engine 212 may specifically subtract a signal from the audio received via the receiver 200 that corresponds to such a level (and/or frequency and/or frequencies) of microphonic noise. Such a subtraction may occur after such audio is downmixed to a kHz range and digitized. Indeed, any operations on audio by the DSP 208, etc., as described herein, are understood to occur at frequencies after audio is downmixed to a kHz range and digitized, except where otherwise indicated.

However, when the microphonic indicator specifically indicates a range of microphonic noise (e.g. which may be flag and/or value based), the microphonic compensation engine 212 may subtract a signal from the audio received via the receiver 200 that corresponds to microphonic noise in such a range.

For example, using the aforementioned flags, when the microphonic indicator comprises a flag of “1”, and/or a range of “0 dB to −2 dB”, the microphonic compensation engine 212 may subtract a signal from the audio received via the receiver 200 that corresponds to microphonic noise in this range, and/or microphonic noise in a middle of this range, or “−1 dB”, for example at a predetermined frequency and/or frequencies (e.g. as measured at the aforementioned factory).

Similarly, when the microphonic indicator comprises a flag of “2”, and/or a range of “−2 dB to −4 dB”, the microphonic compensation engine 212 may subtract a signal from the audio received via the receiver 200 that corresponds to microphonic noise in this range, and/or microphonic noise in a middle of this range, or “−3 dB”, for example at a predetermined frequency and/or frequencies (e.g. as measured at the aforementioned factory).

Similarly, when the microphonic indicator comprises a flag of “3”, and/or a range of “−4 dB to −6 dB”, the microphonic compensation engine 212 may subtract a signal from the audio received via the receiver 200 that corresponds to microphonic noise in this range, and/or microphonic noise in a middle of this range, or “−5 dB”, for example at a predetermined frequency and/or frequencies (e.g. as measured at the aforementioned factory).

However, when the microphonic indicator comprises a flag of “4”, and/or a range of “less than −6 dB”, the microphonic compensation engine 212 may take no action as such a flag and/or range may indicate that no microphonic noise is detected.

Conversely, when the microphonic indicator comprises a flag of “0”, and/or a range of “greater than 0 dB”, the microphonic compensation engine 212 may not be able to compensate for microphonic noise and/or the microphonic compensation engine 212 may attempt to compensate for microphonic noise using highest available compensation parameters (e.g. as used with a flag of “1”), and if such compensation fails to reduce the microphonic noise to values of less than 0 dB, the microphonic compensation engine 212 may implement any suitable action to reduce volume of sound output by the speaker 102.

Alternatively, or in addition, when any compensation of microphonic noise occurring at the microphonic compensation engine 212 fails to reduce the microphonic noise to below a given level (e.g. −4 dB, −5 dB, −6 dB, amongst other possibilities), and the like, the microphonic compensation engine 212 may implement any suitable action to reduce volume of sound output by the speaker 102.

For example, the microphonic compensation engine 212 may reduce volume of the audio received via the receiver 200, in addition to performing the aforementioned compensation, and/or the microphonic compensation engine 212 may control the audio power amplifier 222 to reduce power of the analog processed audio to be output by the speaker 102, and/or the microphonic compensation engine 212 may control the audio processor 206 to reduce power of the processed audio output to the microphonic detection engine 210, and the like.

Hence, while in FIG. 2 the microphonic compensation engine 212 is depicted as being in communication only with the microphonic detection engine 210, and with the RF mixer 202 and the audio processor 206 on the audio path, the microphonic compensation engine 212 may be in communication with any suitable components of the device 100, to control such components to reduce volume of sound output by the speaker 102.

Indeed, while not depicted, suitable components of the device 100 may be in communication via a common bus.

Furthermore, the microphonic detection engine 210 and the microphonic compensation engine 212 may continue to respectively detect and compensate for the microphonic noise in a feedback loop, and, with each instance of the feedback loop where the microphonic noise continues to be detected, the microphonic detection engine 210 may reduce volume of sound emitted by the speaker 102, for example until a predetermined minimum volume is reached, which may be heuristically determined.

Furthermore, such a predetermined minimum volume may be indicated in any suitable manner, such as a minimum volume of audio input to the audio processor 206, a minimum volume of processed audio output by the audio processor 206, and/or a minimum power setting of the audio power amplifier 222. In particular, such a predetermined minimum volume may comprise a volume at which sound emitted by the speaker 102 is distinguishable, by an average listener, from background noise of a given volume, for example as determined heuristically and/or from known human factors parameters and/or standards.

In some examples, when microphonic noise in the compensated processed audio continues to be detected or is no longer detected, by the microphonic detection engine 210, the device 100 may provide, via a transmitter of the receiver/transceiver 200, to an external communication device, a respective notification thereof. For example, as depicted, microphonic detection engine 210 may provide the microphonic indicator to the applications processor 214, which may transmit the microphonic indicator in a notification, and the like, to an external communication device via the transmitter (e.g. via the long dash communication links).

Indeed, the microphonic indicator and/or notification may be provided to the external communication device when any microphonic noise is detected. Alternatively, or in addition, the notification may indicate whether microphonic noise was resolved (e.g. via compensation and/or noise reduction), or resolved.

The external communication device (not depicted in FIG. 2) may comprise any suitable communication device which may be associated with an entity tasked with monitoring functionality of the device 100 (e.g. and other similar communication devices). For example, the external communication device may be operated by an entity which manages the device 100 (e.g. and other communication devices), such as a first responder entity. The microphonic indicator may indicate that the device 100 is functioning (e.g. when the flag is “1” or higher) or not functioning (e.g. when the flag is “0” and/or remains at “0” after microphonic noise compensation and volume reduction). When the device 100 is not functioning, the external entity may recall the device 100. Alternatively, or in addition, when the device 100 is not functioning and/or the microphonic noise was not resolved, a development team associated with the entity may take any suitable remedial action to resolve the microphonic noise, for example once the device 100 is recalled. For example, the engines 210, 212 may need recalibrating, or other components on the audio path may require repair.

Returning to the engines 210, 212, functionality of the engines 210, 212 may be implemented using numerical algorithms and/or machine learning algorithms.

For example, one or more machine learning algorithms of the microphonic detection engine 210 may be trained to detect microphonic noise as described herein, and one or more machine learning algorithms of the microphonic compensation engine 212 may be trained to compensate for microphonic noise as described herein.

Such machine learning algorithms may include, but are not limited to: a deep-learning based algorithm; a neural network; a generalized linear regression algorithm; a random forest algorithm; a support vector machine algorithm; a gradient boosting regression algorithm; a decision tree algorithm; a generalized additive model; evolutionary programming algorithms; Bayesian inference algorithms, reinforcement learning algorithms, and the like. However, any suitable machine learning algorithms and/or deep learning algorithms and/or neural networks are within the scope of present examples.

In particular, at the factory, such one or more machine learning algorithms may be operated in a training mode to train the one or more machine learning algorithms to search for microphonic noise or compensate for microphonic noise. Such training may occur at the device 100 or another similar device. When the training occurs using another similar device, respective machine learning parameters, such as classifiers, and the like, may be provided to the one or more machine learning algorithms of the engines 210, 212 to implement respective functionality thereof.

Attention is now directed to FIG. 3, which depicts a flowchart representative of a method 300 for microphonic noise compensation. The operations of the method 300 of FIG. 3 correspond to the engines 210, 212 and/or machine readable instructions that are executed by the DSP 208. The method 300 of FIG. 3 is one way that the device 100 may be configured. Furthermore, the following discussion of the method 300 of FIG. 3 will lead to a further understanding of the device 100, and its various components.

The method 300 of FIG. 3 need not be performed in the exact sequence as shown and likewise various blocks may be performed in parallel rather than in sequence. Accordingly, the elements of method 300 are referred to herein as “blocks” rather than “steps.” The method 300 of FIG. 3 may be implemented on variations of the device 100 of FIG. 1, as well.

Furthermore it is understood that blocks 302, 304, 306, 308, 314, 320 are performed by the microphonics detection engine 210, and blocks 310, 312, 316, 318, 322 are performed by the microphonics compensation engine 212.

At a block 302, the microphonic detection engine 210 searches for microphonic noise in processed audio (e.g. received from the audio processor 206) according to one or more predetermined microphonic parameters.

At a block 304, the microphonic detection engine 210 determines whether microphonic noise is detected in the processed audio.

When no microphonic noise is detected, or the microphonic noise is detected below a given value, such as −4 db, −5 db, −6 db, and the like, (e.g. a “NO” decision at the block 304), the microphonic detection engine 210 continues to search for microphonic noise in the processed audio at the block 302.

When the microphonic noise is detected (e.g. a “YES” decision at the block 304), at an optional block 306, the microphonic detection engine 210 may determine whether the microphonic noise is a first detection of microphonic noise, or a subsequent detection of microphonic noise (e.g. a first or second time for implementing the block 304). While not depicted, the device 100 may implement a detection counter that, upon a first detection of microphonic noise, is incremented from “0” to “1”.

When detection of the microphonic noise is a first detection of microphonic noise is detected (e.g. a “YES” decision at the block 306), at a block 308, the microphonic detection engine 210 outputs a microphonic indicator 309 to the microphonic detection engine 210 to cause the microphonic compensation engine to compensate for the microphonic noise in the audio received via the receiver 200.

At a block 310, the microphonic detection engine 210 receives the microphonic indicator 309.

At a block 312, the microphonic detection engine 210 responsively compensates for the microphonic noise in the audio received via the receiver 200, prior to processing of the audio by the audio processor 206.

In some examples, the method 300 may end at the block 312, and/or, as depicted, the method 300 may repeat from the block 302, for example such that the microphonic detection engine 210 continues to search for microphonic noise in the processed audio, and the microphonic detection engine 210 continues to compensate for the microphonic noise. Indeed, ignoring for a moment the optional block 306, the blocks 302, 304, 308 310, 312 may form a feedback loop such that as microphonic noise increases or decreases, compensation for the microphonic noise may be adjusted accordingly.

For example, presuming block 306 is omitted, when microphonic noise was previously detected and compensated for during implementation of the blocks 302, 304, 308, 310, 312, and a further implementation of the blocks 302, 304, 308, 310, 312 continues to detect microphonic noise, compensation for the microphonic noise may be increased (e.g. in stepwise increments, for example of 1% increments, 2% increments, 5% increments, and/or in 0.1 dB increments, 0.2 dB increments, 0.5 dB increments, amongst other possibilities) until microphonic noise is no longer detected (e.g. a “NO” decision at the block 304) or some maximum compensation is reached. Such maximum compensation may correspond to the maximum compensation that the microphonic compensation engine 212 is trained to apply to the audio from the receiver 200.

Similarly, again presuming block 306 is omitted, when microphonic noise was previously detected and compensated for during implementation of the blocks 302, 304, 308, 310, 312, and a further implementation of the blocks 302, 304, 308, 310, 312 detect no microphonic noise, compensation for the microphonic noise may be reduced (e.g. in stepwise increments, for example of 1% increments, 2% increments, 5% increments, and/or in 0.1 dB increments, 0.2 dB increments, 0.5 dB increments, amongst other possibilities) until microphonic noise is again detected, or compensation ends.

Examples at which the block 306 is implemented are next described.

In particular, after implementation of the block 312, the blocks 302, 304 are again implemented. When a “YES” decision at the block 304 (e.g., microphonic noise is still detected), the microphonic detection engine 210 determines, at the block 306 that detection of the microphonic noise is a not a first detection of microphonic noise (e.g. a subsequent detection of microphonic noise), and another feedback loop is implemented that includes volume reduction. Put another way, the aforementioned detection counter may be incremented from “1” to “2”, and for detection counter values greater than “1”, a “NO” decision occurs at the block 306.

In particular, when detection of the microphonic noise is not a first detection of microphonic noise is detected (e.g. a “NO” decision at the block 306), at a block 314, similar to the block 308, the microphonic detection engine 210 again outputs a microphonic indicator 315 to the microphonic detection engine 210, to cause the microphonic detection engine 210 to compensate for the microphonic noise in the audio received via the receiver 200.

At a block 316, similar to the block 310, the microphonic detection engine 210 receives the microphonic indicator 315, and at a block 318, similar to the block 312, the microphonic detection engine 210 again compensates for microphonic noise.

At a block 320, similar to the block 306, the microphonic detection engine 210 continues to determine whether microphonic noise is detected (and which is understood to include searching for microphonic noise, similar to the block 302).

However, when the microphonic noise continues to be detected (e.g. a “YES” decision at the block 320), at a block 322, the microphonic detection engine 210 reduces volume of sound output by the speaker 102, as described herein.

The method 300 repeats from the block 314 that, when again implemented, is assumed to again include searching for microphonic noise, similar to the block 302.

Indeed, it is understood in the method 300 that the block 302 may be continually implemented (e.g. and/or periodically implemented) such that when microphonic noise is detected, or changes in microphonic noise occur, a respective microphonic indicator (e.g. similar to the indicators 309, 315) are output to the microphonic detection engine 210.

The feedback loop represented by the blocks 314, 316, 318, 320, 322 may continue until microphonic noise is no longer detected at the block 320 (e.g. a “NO” decision at the block 320), and the method 300 may repeat from the block 302 (e.g. at which point a detection counter associated with the block 306 may be reset to “0”), or the method 300 may end.

Alternatively, or in addition, the feedback loop represented by the blocks 314, 316, 318, 320, 322 may continue until a predetermined minimum volume is reached, and the method 300 may end, or the method may repeat.

Indeed, in each instance of the feedback loop represented by the blocks 314, 316, 318, 320, 322, the volume may be incrementally reduced at the block 322 (e.g. in 5% increments, 10% increments, 15% increments, amongst other possibilities), and when the predetermined minimum volume is reached, the method 300 may

The method 300 may be adapted to include any suitable features.

For example, the method 300 may further comprise, via the microphonic detection engine 210, continuing to search for the microphonic noise in compensated processed audio (e.g. as received from the audio processor 206); and, when the microphonic noise in the compensated processed audio continues to be detected or is no longer detected, provide, via the receiver/transmitter 200, to an external communication device, a respective notification thereof. For example, the microphonic detection engine 210 may provide the microphonic indicator to the applications processor 214 which may transmit the microphonic indicator, in the form of a notification, to the external communication device via the receiver/transmitter 200.

The method 300 may further comprise, the microphonic detection engine 210: searching (e.g. at the block 302) for microphonic noise in the processed audio (e.g. received from the audio processor 206) according to the one or more predetermined microphonic parameters that are at least partially range based; determine (e.g. at the block 302) one or more of: a level (e.g. in dB) of the microphonic noise; and a range (e.g. in dB), of a plurality of ranges, in which the level of the microphonic noise is located; and generate (e.g. at the block 308 and/or the block 314) the microphonic indicator 309, 315 to indicate one or more of the level and the range of the microphonic noise.

In examples where the microphonic indicator 309, 315 is indicative of a level of the microphonic noise, the method 300 may further comprise the microphonic detection engine 210 (e.g. at the block 312 and/or the block 318): compensating for the microphonic noise in the audio received via the receiver 200 according to the level.

In examples where the microphonic indicator 309, 315 is indicative of a range, of a plurality of ranges, in which a level of the microphonic noise is located, the method 300 may further comprise the microphonic detection engine 210 (e.g. at the block 312 and/or the block 318): compensating for the microphonic noise in the audio received via the receiver 200 according to the range.

In some examples, the method 300 may further comprise the microphonic detection engine 210 (e.g. at the block 312 and/or the block 318): compensating for the microphonic noise in the audio received via the receiver 200 at least partially based on the one or more predetermined microphonic parameters. For example, the aforementioned flags may be based on the one or more predetermined microphonic parameters, and the microphonic detection engine 210 may compensate for the microphonic noise based on a value of a flag.

In some examples, the method 300 may further comprise, when the microphonic detection engine 210 continues to detect microphonic noise in the processed audio after the microphonic detection engine 210 compensates for the microphonic noise in the audio: reducing volume of sound emitted by the speaker 102; and continue to compensate for the microphonic noise in the audio received via the receiver 200, prior to processing of the audio by the audio processor 206.

In some examples, the method 300 may further comprise, the microphonic detection engine 210 and the microphonic detection engine 210 continuing to respectively detect and compensate for the microphonic noise in a feedback loop, and, with each instance of the feedback loop where the microphonic noise continues to be detected, the microphonic detection engine 210 reduces volume of sound emitted by the speaker until the microphonic noise is no longer detected.

In some examples, the method 300 may further comprise, the microphonic detection engine 210 and the microphonic detection engine 210 continuing to respectively detect and compensate for the microphonic noise in a feedback loop, and, with each instance of the feedback loop where the microphonic noise continues to be detected, the microphonic detection engine 210 reduces volume of sound emitted by the speaker until a predetermined minimum volume is reached.

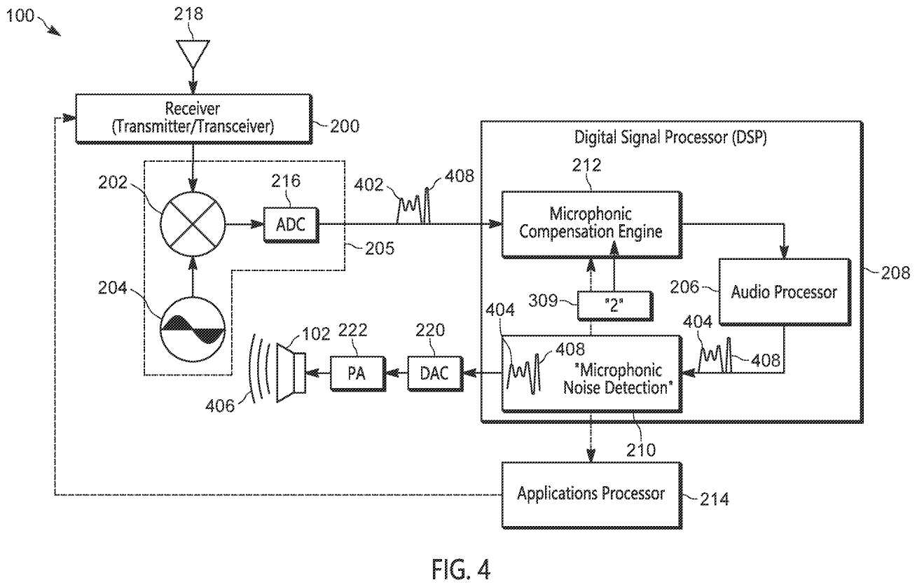

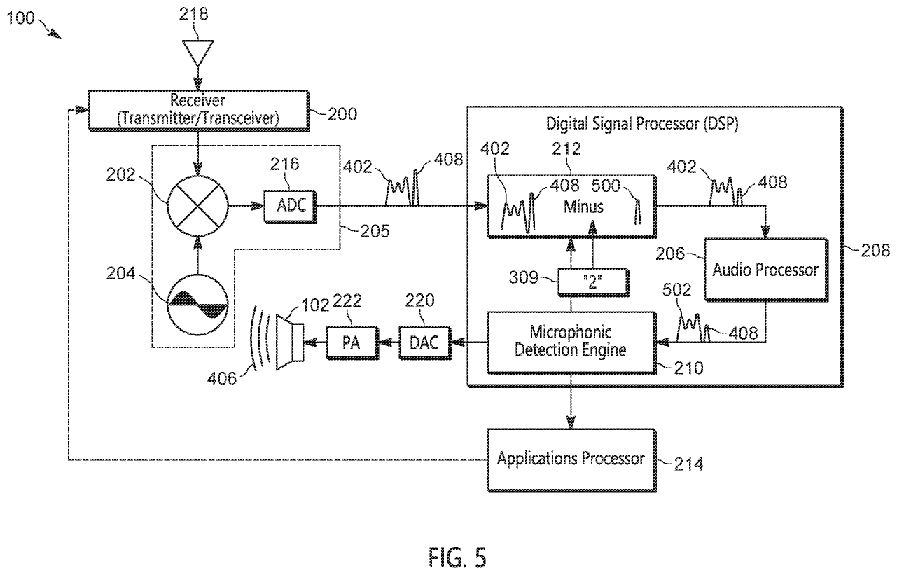

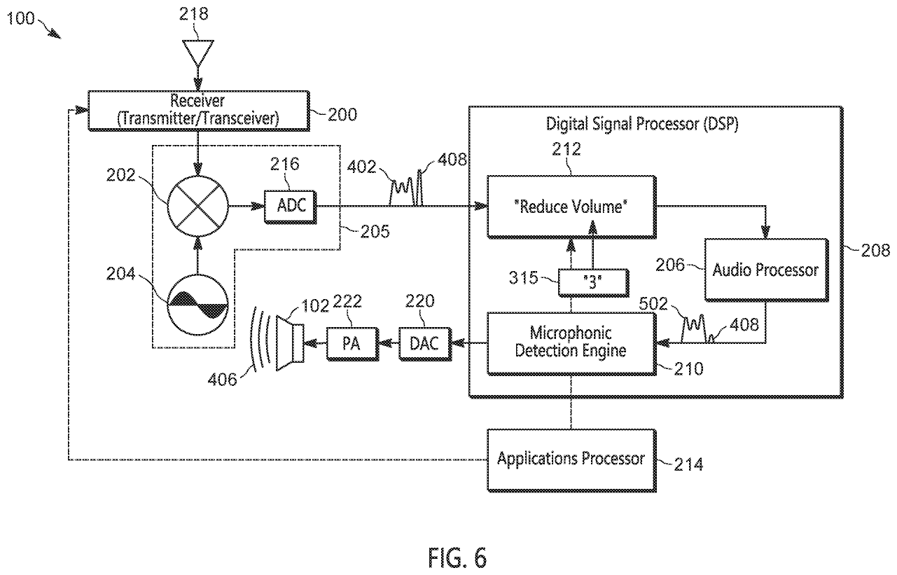

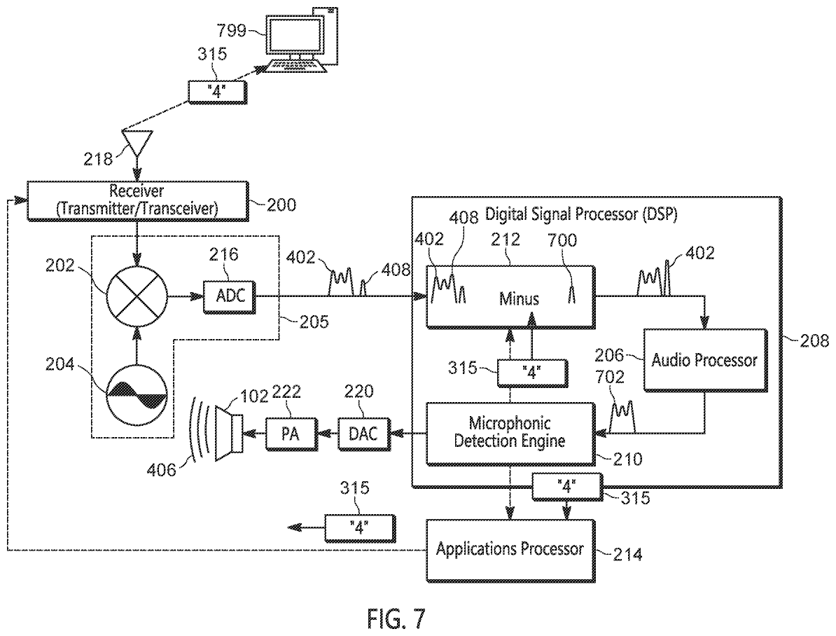

Attention is next directed to FIG. 4, FIG. 5, FIG. 6 and FIG. 7, which depict aspects of the method 300. FIG. 4, FIG. 5, FIG. 6 and FIG. 7 are similar to FIG. 2, with like components having like numbers.

With attention first directed to FIG. 4, which depicts the device 100 before microphonic noise compensation occurs, audio 402 is received via the receiver 200, downmixed via the RF mixer 202 and VCO 204, digitized by the ADC 216, and processed by the audio processor 206 on the audio path to generate processed audio 404, which is provided to the speaker 102 (e.g. via the microphonic detection engine 210, the DAC 220 and the audio power amplifier 222), which outputs sound 406. As depicted the sound 406 causes the VCO 204 to vibrate, which introduces microphonic noise 408 into the audio 402 and the processed audio 404, such that the sound 406 is understood to include the aforementioned howling sound. The noise 408 is understood to persist after the downmixing.

As depicted, the microphonic detection engine 210 searches (e.g. at the block 302 of the method 300) for microphonic noise in the processed audio 404 and detects (e.g. a “YES” decision at the block 304 of the method 300) the microphonic noise 408 in the processed audio 404.

Presuming a “YES” decision at the block 306, the microphonic detection engine 210 provides (e.g. at the block 308 of the method 300) the microphonic indicator 309 to the microphonic compensation engine 212. As depicted, the microphonic indicator 309 indicates a flag of “2”, which may indicate that the microphonic noise 408 is in a range of “−2 dB to −4 dB”, as previously described. The microphonic compensation engine 212 receives the microphonic indicator 309 (e.g. at the block 310 of the method 300).

Turning to FIG. 5, having received the microphonic indicator 309 of “2”, the microphonic compensation engine 212 compensates (e.g. at the block 312 of the method 300) for the microphonic noise 408 by subtracting, from the audio 402, a signal 500 corresponding to microphonic noise in a range of “−2 dB to −4 dB”, for example the signal 500 may be “−3 dB”, and may be at a same frequency as the microphonic noise 408. The microphonic compensation engine 212 outputs the audio 402 with the microphonic noise 408 reduced. The audio processor 206 processes the audio 402 with the microphonic noise 408 as reduced to generate processed audio 502 that includes the microphonic noise 408 as reduced.

Turning now to FIG. 6, which follows from FIG. 5, it is understood that the audio 402 continues to include the microphonic noise 408, and that the microphonic compensation engine 212 continues to reduce the microphonic noise 408 to compensate for the microphonic noise 408. Presuming that another attempt to reduce the microphonic noise 408 (e.g. at the blocks 314, 316, 318) results in the microphonic noise 408 continuing to be detected by the microphonic detection engine 210 (e.g. as indicated by the indicator 315 having a flag of “3”, indicating that the microphonic noise 408 is now in a range of “−4 dB to −6 dB”), the microphonic compensation engine 212 may implement any suitable action to reduce (e.g. at the block 322 of the method 300) the volume of the sound 406 output by the speaker 102.

For example, as depicted in FIG. 7, which follows from FIG. 6, the sound 406 is reduced, resulting in lower microphonic noise 408 in the audio 402 received via the receiver 200. The microphonic compensation engine 212 (e.g. on the basis of the indicator 315 of “3”, or another value that occurs after the volume of the sound 406 is reduced), subtracts, from the audio 402, a signal 700 corresponding to microphonic noise in a range of “−4 dB to −6 dB”, for example the signal 700 may be “−4 dB”, and may be at a same frequency as the microphonic noise 408. The microphonic compensation engine 212 outputs the audio 402 with the microphonic noise 408 eliminated. The audio processor 206 processes the audio 402 with the microphonic noise 408 eliminated to generate processed audio 702 used to drive the speaker 102.

FIG. 7 further depicts the microphonic detection engine 210 determining a microphonic indicator 315 of “4”, which may indicate to the microphonic compensation engine 212 that the microphonic noise 408 has been eliminated, which may cause the microphonic detection engine 210 to below to reduce compensation or maintain compensation, for example in a feedback loop with the microphonic detection engine 210.

As depicted the microphonic detection engine 210 provides the microphonic indicator 315 to the applications processor 214, which controls receiver/transmitter 200 to transmit the microphonic indicator 315 to an external computing device 799, via the antenna 218.

As should be apparent from this detailed description above, the operations and functions of the electronic computing device are sufficiently complex as to require their implementation on a computer system, and cannot be performed, as a practical matter, in the human mind. Electronic computing devices such as set forth herein are understood as requiring and providing speed and accuracy and complexity management that are not obtainable by human mental steps, in addition to the inherently digital nature of such operations (e.g., a human mind cannot interface directly with RAM or other digital storage, cannot transmit or receive electronic messages, electronically encoded video, electronically encoded audio, etc., and cannot compensate for microphonic noise in a feedback loop, among other features and functions set forth herein).

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

Also, it should be understood that the illustrated components, unless explicitly described to the contrary, may be combined or divided into separate software, firmware, and/or hardware. For example, instead of being located within and performed by a single electronic processor, logic and processing described herein may be distributed among multiple electronic processors. Similarly, one or more memory modules and communication channels or networks may be used even if embodiments described or illustrated herein have a single such device or element. Also, regardless of how they are combined or divided, hardware and software components may be located on the same computing device or may be distributed among multiple different devices. Accordingly, in this description and in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively.

It will be appreciated that some embodiments may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an embodiment can be implemented as a computer-readable storage medium having computer readable code stored thereon for programming a computer (e.g., comprising a processor) to perform a method as described and claimed herein. Any suitable computer-usable or computer readable medium may be utilized. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. In the context of this document, a computer-usable or computer-readable medium may be any medium that can contain, store, communicate, propagate, or transport the program for use by or in connection with the instruction execution system, apparatus, or device.

Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation. For example, computer program code for carrying out operations of various example embodiments may be written in an object oriented programming language such as Java, Smalltalk, C++, Python, or the like. However, the computer program code for carrying out operations of various example embodiments may also be written in conventional procedural programming languages, such as the “C” programming language or similar programming languages. The program code may execute entirely on a computer, partly on the computer, as a stand-alone software package, partly on the computer and partly on a remote computer or server or entirely on the remote computer or server. In the latter scenario, the remote computer or server may be connected to the computer through a local area network (LAN) or a wide area network (WAN), or the connection may be made to an external computer (for example, through the Internet using an Internet Service Provider).

The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “one of”, without a more limiting modifier such as “only one of”, and when applied herein to two or more subsequently defined options such as “one of A and B” should be construed to mean an existence of any one of the options in the list alone (e.g., A alone or B alone) or any combination of two or more of the options in the list (e.g., A and B together).

A device or structure that is “configured” in a certain way is configured in at least that way, but may also be configured in ways that are not listed.

The terms “coupled”, “coupling” or “connected” as used herein can have several different meanings depending on the context in which these terms are used. For example, the terms coupled, coupling, or connected can have a mechanical or electrical connotation. For example, as used herein, the terms coupled, coupling, or connected can indicate that two elements or devices are directly connected to one another or connected to one another through intermediate elements or devices via an electrical element, electrical signal or a mechanical element depending on the particular context.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

What is claimed is:

1. A device comprising:
a speaker; a receiver; an audio processor configured to: process audio received via the receiver; and output processed audio to the speaker; a microphonic detection engine; and a microphonic compensation engine,
the microphonic detection engine configured to:
search for microphonic noise in the processed audio according to one or more predetermined microphonic parameters; and
when the microphonic noise is detected: output a microphonic indicator to the microphonic compensation engine to cause the microphonic compensation engine to compensate for the microphonic noise in the audio;
the microphonic compensation engine configured to:
receive the microphonic indicator; and responsively compensate for the microphonic noise in the audio received via the receiver, prior to processing of the audio by the audio processor.

2. The device of claim 1, further comprising a transmitter, wherein the microphonic detection engine is further configured to:
continue to search for the microphonic noise in compensated processed audio; and,
when the microphonic noise in the compensated processed audio continues to be detected or is no longer detected, provide, via the transmitter, to an external communication device, a respective notification thereof.

3. The device of claim 1, wherein the one or more predetermined microphonic parameters are indicative of one or more predetermined microphonic audio data sets combined with one or more clean audio samples.

4. The device of claim 1, wherein the microphonic detection engine is further configured to:
search for microphonic noise in the processed audio according to the one or more predetermined microphonic parameters that are at least partially range based;
determine one or more of: a level of the microphonic noise; and a range, of a plurality of ranges, in which the level of the microphonic noise is located; and
generate the microphonic indicator to indicate one or more of the level and the range of the microphonic noise.

5. The device of claim 1, wherein the microphonic indicator is indicative of a level of the microphonic noise, and the microphonic compensation engine is further configured to:
compensate for the microphonic noise in the audio received via the receiver according to the level.

6. The device of claim 1, wherein the microphonic indicator is indicative of a range, of a plurality of ranges, in which a level of the microphonic noise is located, and the microphonic compensation engine is further configured to:
compensate for the microphonic noise in the audio received via the receiver according to the range.

7. The device of claim 1, wherein the microphonic compensation engine is further configured to compensate for the microphonic noise in the audio at least partially based on the one or more predetermined microphonic parameters.

8. The device of claim 1, wherein the microphonic compensation engine is further configured to, when the microphonic detection engine continues to detect microphonic noise in the processed audio after the microphonic compensation engine compensates for the microphonic noise in the audio:
reduce volume of sound emitted by the speaker; and
continue to compensate for the microphonic noise in the audio received via the receiver, prior to processing of the audio by the audio processor.

9. The device of claim 1, wherein the microphonic detection engine and the microphonic compensation engine continue to respectively detect and compensate for the microphonic noise in a feedback loop, and, with each instance of the feedback loop where the microphonic noise continues to be detected, the microphonic compensation engine reduces volume of sound emitted by the speaker until the microphonic noise is no longer detected.

10. The device of claim 1, wherein the microphonic detection engine and the microphonic compensation engine continue to respectively detect and compensate for the microphonic noise in a feedback loop, and, with each instance of the feedback loop where the microphonic noise continues to be detected, the microphonic compensation engine reduces volume of sound emitted by the speaker until a predetermined minimum volume is reached.

11. The device of claim 1, further comprising a digital signal processor (DSP) and an applications processor,
wherein the audio processor is implemented at the DSP, and
wherein the microphonic detection engine and the microphonic compensation engine are implemented at one or more of the DSP and the applications processor.

12. The device of claim 1, further comprising one or more of a land mobile radio (LMR), a digital mobile radio (DMR), a two-way radio, and first responder radio.

13. A method comprising:
processing, at an audio processor, audio received via a receiver to generate processed audio;
searching, via a microphonic detection engine, for microphonic noise in the processed audio according to one or more predetermined microphonic parameters;
when the microphonic noise is detected: outputting, via the microphonic detection engine, a microphonic indicator to a microphonic compensation engine;
receiving, at the microphonic compensation engine, the microphonic indicator; and
responsively compensating, via the microphonic compensation engine, for the microphonic noise in the audio received via the receiver, prior to processing of the audio by the audio processor.

14. The method of claim 13, further comprising:
continuing to search for the microphonic noise in compensated processed audio; and,
when the microphonic noise in the compensated processed audio continues to be detected or is no longer detected, provide, via a transmitter, to an external communication device, a respective notification thereof.

15. The method of claim 13, wherein the one or more predetermined microphonic parameters are indicative of one or more predetermined microphonic audio data sets combined with one or more clean audio samples.

16. The method of claim 13, further comprising:
searching for microphonic noise in the processed audio according to the one or more predetermined microphonic parameters that are at least partially range based;
determining one or more of: a level of the microphonic noise; and a range, of a plurality of ranges, in which the level of the microphonic noise is located; and
generating the microphonic indicator to indicate one or more of the level and the range of the microphonic noise.

17. The method of claim 13, wherein the microphonic indicator is indicative of a level of the microphonic noise, and the method further comprises:
compensating for the microphonic noise in the audio received via the receiver according to the level.

18. The method of claim 13, wherein the microphonic indicator is indicative of a range, of a plurality of ranges, in which a level of the microphonic noise is located, and the method further comprises:
compensating for the microphonic noise in the audio received via the receiver according to the range.

19. The method of claim 13, further comprising:
when the microphonic detection engine continues to detect microphonic noise in the processed audio after the microphonic compensation engine compensates for the microphonic noise in the audio:
reducing volume of sound emitted by a speaker; and
continuing to compensate for the microphonic noise in the audio received via the receiver, prior to processing of the audio by the audio processor.

20. The method of claim 13, wherein the microphonic detection engine and the microphonic compensation engine continue to respectively detect and compensate for the microphonic noise in a feedback loop, and, with each instance of the feedback loop where the microphonic noise continues to be detected, the microphonic compensation engine reduces volume of sound emitted by a speaker until the microphonic noise is no longer detected, or the microphonic compensation engine reduces volume of sound emitted by the speaker until a predetermined minimum volume is reached.
